(19) United States
(12) Patent Application Publication
(10) Pub. No.: US 2026/0033300 A1
(43) Pub. Date: Jan. 29, 2026

(54) SEMICONDUCTOR DEVICES AND METHODS OF MANUFACTURE

(71) Applicant: Taiwan Semiconductor Manufacturing Co., Ltd., Hsinchu (TW)

(72) Inventors: Guan-Ren Wang, Hsinchu (TW); Chu-Hsuan Sha, Taipei City (TW); Chun-Yu Liu, New Taipei City (TW); Yung-Ta Chen, Taichung City (TW); Chung Chuan Huang, Hsinchu (TW); Yuan-Bang Lee, Tongxiao Town (TW); Tsung-Han Tsai, New Taipei City (TW); Wei-Yeh Tang, Yangmei City (TW); Huang-Ming Chen, Hsinchu (TW); Szuya Liao, Zhubei (TW)

(21) Appl. No.: 18/999,763

(22) Filed: Dec. 23, 2024

Related U.S. Application Data
(60) Provisional application No. 63/674,724, filed on Jul. 23, 2024.
(60) Provisional application No. 63/694,255, filed on Sep. 13, 2024.

(51) Int. Cl. H01L 21/263; H01L 21/268; H01L 21/67; H10D 30/00; H10D 30/01; H10D 62/10; H10D 84/85

(52) U.S. Cl. CPC H01L 21/2636; H01L 21/268; H01L 21/67103; H01L 21/67115; H10D 30/014; H10D 30/019; H10D 30/501; H10D 62/121; H10D 84/851

(57) ABSTRACT

A method of manufacturing semiconductor devices, the semiconductor devices manufactured, and apparatuses for forming the semiconductor devices are described in which by-products from etching processes are independently heated separately from a semiconductor wafer. In embodiments a dielectric material is deposited into a trench over a semiconductor substrate and the dielectric material is recessed with an etching process. The etching process includes heating the semiconductor substrate and separately heating a by-product of the etching process.

### PRIORITY CLAIM AND CROSS-REFERENCE

This application claims the benefit of the following provisionally filed U.S. Patent applications: Application No. 63/674,724, filed on Jul. 23, 2024, and entitled “Enhance Etch Control of Vertical Patterning by Extra Heating Source,” and Application No. 63/694,255, filed on Sep. 13, 2024, and entitled “Enhance Etch Control of Vertical Patterning by Extra Heating Source,” which applications are hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistors, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of example Complementary Field-Effect Transistors (CFETs) in accordance with some embodiments.

FIGS. 2 through 14 are views of intermediate stages in the manufacturing of CFETs in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be described with respect to a particular embodiment in which by-products of an etching process are heated independently from the semiconductor wafer in the manufacture of a Complementary Field-Effect Transistor (CFET) structure. The embodiments described herein, however, are intended to be illustrative of the ideas presented and are not intended to limit the embodiments to the precise description presented. Rather, the ideas may be implemented in a wide range of processes and devices, and all such processes and devices are fully intended to be included within the scope of the embodiments.

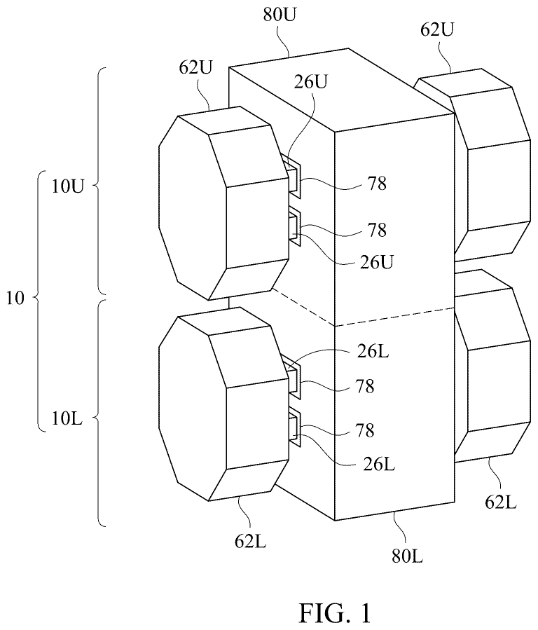

FIG. 1 illustrates an example of a stacking transistor 10 (including FETs (transistors) 10U and 10L) in accordance with some embodiments. FIG. 1 is a three-dimensional view, and some features of the stacking transistor are omitted for illustration clarity.

The stacking transistor includes multiple vertically stacked FETs. For example, a stacking transistor may include a lower nanostructure-FET 10L of a first device type (e.g., n-type/p-type) and an upper nanostructure-FET 10U of a second device type (e.g., p-type/n-type). When the stacking transistor is a CFET, the second device type of the upper nanostructure-FET 10U is opposite to the first device type of the lower nanostructure-FET 10L. The nanostructure-FETs 10U and 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors (e.g., finFETs, or the like) as well.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. Each of the source/drain regions 62 may refer to a source or a drain, individually or collectively dependent upon the context. Isolation features (not shown) may be formed to separate desired ones of the source/drain regions 62 and/or desired ones of the gate electrodes 80.

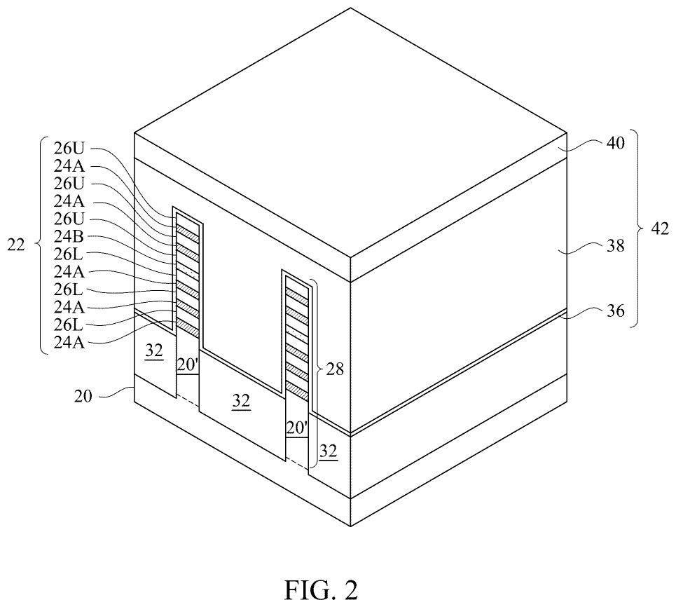

In FIG. 2, a wafer, which includes semiconductor substrate 20, is provided. Semiconductor substrate 20 may be a semiconductor substrate, such as a bulk semiconductor, which may be doped (e.g., with a p-type or an n-type dopant) or undoped. Other substrates, such as a multi-layered or gradient substrate may also be used. In some embodiments, the semiconductor material of the semiconductor substrate 20 may include silicon, germanium, carbon-doped silicon, a III-V compound semiconductor; or the like, or combinations thereof.

Semiconductor strips 28 are formed extending upwards from the semiconductor substrate 20. Each of semiconductor strips 28 includes semiconductor strip 20′ (patterned portions of the semiconductor substrate 20, also referred to as semiconductor fins 20′) and a multi-layer stack 22. The stacked component of the multi-layer stack 22 is referred to as nanostructures hereinafter. Specifically, the multi-layer stack 22 includes dummy nanostructures 24A, dummy nanostructures 24B, lower semiconductor nanostructures 26L, and upper semiconductor nanostructures 26U. Dummy nanostructures 24A and dummy nanostructures 24B may further be collectively referred to as dummy nanostructures 24, and the lower semiconductor nanostructures 26L and the upper semiconductor nanostructures 26U may further be collectively referred to as semiconductor nanostructures 26.

The dummy nanostructures 24A are formed of a first semiconductor material, and the dummy nanostructures 24B is formed of a second semiconductor material different from the first semiconductor material. The first and second semiconductor materials may be selected from the candidate semiconductor materials of the semiconductor substrate 20. The first and second semiconductor materials have a high etching selectivity to one another. As such, the dummy nanostructures 24B may be removed at a faster rate than the dummy semiconductor layers 24A in subsequent processes.

The semiconductor nanostructures 26 (including the lower semiconductor nanostructures 26L and upper semiconductor nanostructures 26U) are formed of one or more third semiconductor material(s). The third semiconductor material(s) may be selected from the candidate semiconductor materials of the semiconductor substrate 20. The lower semiconductor nanostructures 26L and the upper semiconductor nanostructures 26U may be formed of the same semiconductor material, or may be formed of different semiconductor materials. Further, the first and second semiconductor materials of the dummy nanostructures 24 have a high etching selectivity to the third semiconductor material(s) of the semiconductor nanostructures 26. As such, the dummy nanostructure 24 may be selectively removed in subsequent process steps without significantly removing the semiconductor nanostructures 26. In some embodiments, the dummy semiconductor nanostructures 24A are formed of or comprise silicon germanium, the semiconductor layers 26 are formed of silicon, and the dummy nanostructures 24B may be formed of germanium or silicon germanium with a higher germanium atomic percentage than the semiconductor nanostructures 24A.

The lower semiconductor nanostructures 26L will provide channel regions for lower nanostructure-FETs of the CFETs. The upper semiconductor nanostructures 26U will provide channel regions for upper nanostructure-FETs of the CFETs. The semiconductor nanostructures 26 that are immediately above/below (e.g., in contact with) the dummy nanostructures 24B may be used for isolation and may or may not act as channel regions for the CFETs. The dummy nanostructures 24B will be subsequently replaced with isolation structures that define boundaries of the lower nanostructure-FETs and the upper nanostructure-FETs.

To form the semiconductor strips 28, layers of the first, second, and third semiconductor materials (arranged as illustrated and described above) may be deposited over the semiconductor substrate 20. The layers of the first, second, and third semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like. Then, a patterning process may be applied to the layers of the first, second, and third semiconductor materials as well as the semiconductor substrate 20 to define the semiconductor strips 28, which includes the semiconductor strips 20′, the dummy nanostructures 24, and the semiconductor nanostructures 26.

The semiconductor fins and the nanostructures may be patterned by any suitable method. For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the semiconductor substrate 20. The etching may be performed by any acceptable etch process, such as a Reactive Ion Etch (RIE), Neutral Beam Etch (NBE), the like, or a combination thereof. The etching may be anisotropic.

As also illustrated by FIG. 2, STI regions 32 are formed over the semiconductor substrate 20 and between adjacent semiconductor strips 28. STI regions 32 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 32 may include depositing the dielectric layer(s), and performing a planarization process such as a Chemical Mechanical Polish (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 32 include silicon oxide formed by an FCVD process, followed by an anneal process. Then, the dielectric layers(s) are recessed to define the STI regions 32. The dielectric layer(s) maybe recessed such that upper portions of semiconductor strips 28 (including multi-layer stacks 22) protrude higher than the remaining STI regions 32.

After the STI regions 32 are formed, dummy gate stacks 42 may be formed over and along sidewalls of the upper portions of the semiconductor strips 28 (the portions that protrude higher than the STI regions 32). Forming the dummy gate stacks 42 may include forming dummy dielectric layer 36 on the semiconductor strips 28. Dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like. Next, the mask layer 40 may be patterned through photolithography and etching processes to form a mask, which is then used to etch and pattern dummy gate layer 38, and possibly the dummy dielectric layer 36. The remaining portions of mask layer 40, dummy gate layer 38, and dummy dielectric layer 36 form dummy gate stacks 42.

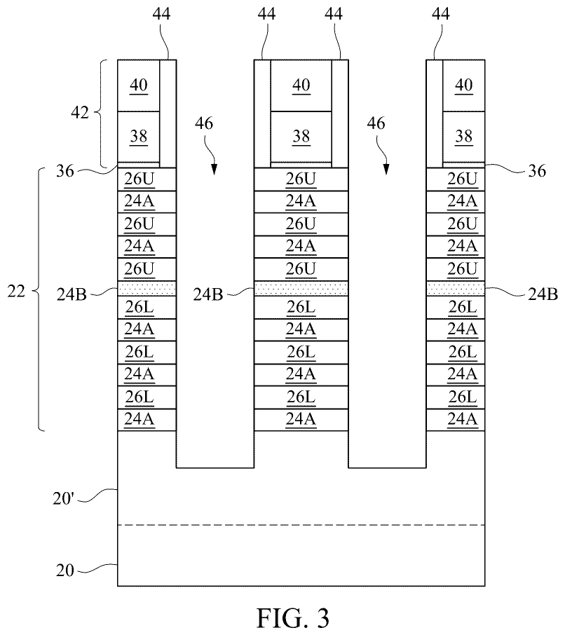

In FIG. 3, gate spacers 44 and source/drain recesses 46 or trenches are formed. First, the gate spacers 44 are formed over the multi-layer stacks 22 and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

Subsequently, source/drain recesses 46 are formed in semiconductor strips 28. The source/drain recesses 46 are formed through etching, and may extend through the multi-layer stacks 22 and into the semiconductor strips 20′. The bottom surfaces of the source/drain recesses 46 may be at a level above, below, or level with the top surfaces of the STI regions 32. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon source/drain recesses 46 reaching a desired depth.

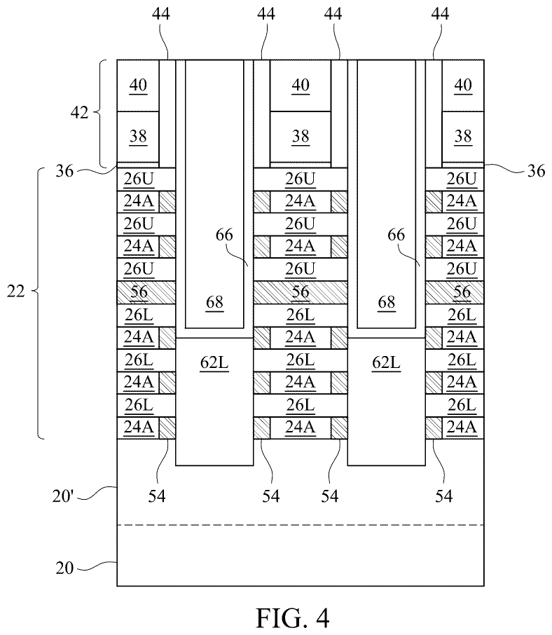

In FIG. 4, inner spacers 54 and dielectric isolation layers 56 are formed. Forming inner spacers 54 and dielectric isolation layers 56 may include an etching process that laterally etches the dummy nanostructures 24A and removes the dummy nanostructure 24B. The etching process may be isotropic and may be selective to the material of the dummy nanostructures 24, so that the dummy nanostructures 24 are etched at a faster rate than the semiconductor nanostructures 26. The etching process may also be selective to the material of the dummy nanostructures 24B, so that the dummy nanostructures 24B are etched at a faster rate than the dummy nanostructures 24A. In this manner, the dummy nanostructures 24B may be completely removed from between the lower semiconductor nanostructures 26L (collectively) and the upper semiconductor nanostructures 26U (collectively) without completely removing the dummy nanostructures 24A. In some embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etch process may comprise a dry etch process using chlorine gas, with or without a plasma. Because the dummy gate stacks 42 warp around sidewalls of the semiconductor nanostructures 26 (see FIG. 2), the dummy gate stacks 42 may support the upper semiconductor nanostructures 26U so that the upper semiconductor nanostructures 26U do not collapse upon removal of the dummy nanostructures 24B. Further, although sidewalls of the dummy nanostructures 24A are illustrated as being straight after the etching, the sidewalls may be concave or convex.

Inner spacers 54 are formed on sidewalls of the recessed dummy nanostructures 24A, and dielectric isolation layers 56 are formed between the upper semiconductor nanostructures 26U (collectively) and the lower semiconductor nanostructures 26L (collectively). As subsequently described in greater detail, source/drain regions will be subsequently formed in the source/drain recesses 46, and the dummy nanostructures 24A will be replaced with corresponding gate structures. The inner spacers 54 act as isolation features between the subsequently formed source/drain regions and the subsequently formed gate structures. Further, the inner spacers 54 may be used to prevent damage to the subsequently formed source/drain regions by subsequent etch processes, such as the etch processes used to form gate structures. Dielectric isolation layers 56, on the other hand, are used to isolate the upper semiconductor nanostructures 26U (collectively) from the lower semiconductor nanostructures 26L (collectively). Further, middle semiconductor nanostructures (ones of the semiconductor nanostructures 26 in contact with the dielectric isolation layers 56) and the dielectric isolation layers 56 may define the boundaries of the lower nanostructure-FETs and the upper nanostructure-FETs.

The inner spacers 54 and the dielectric isolation layers 56 may be formed by conformally depositing an insulating material in the source/drain recesses 46, on sidewalls of the dummy nanostructures 24, and between the upper and lower semiconductor nanostructures 26U and 26L, and then etching the insulating material. The insulating material may be a hard dielectric material, such as a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic or isotropic. The insulating material, when etched, has portions remaining in the sidewalls of the dummy nanostructures 26A (thus forming the inner spacers 54) and has portions remaining in between the upper and lower semiconductor nanostructures 26U and 26L (thus forming the dielectric isolation layers 56).

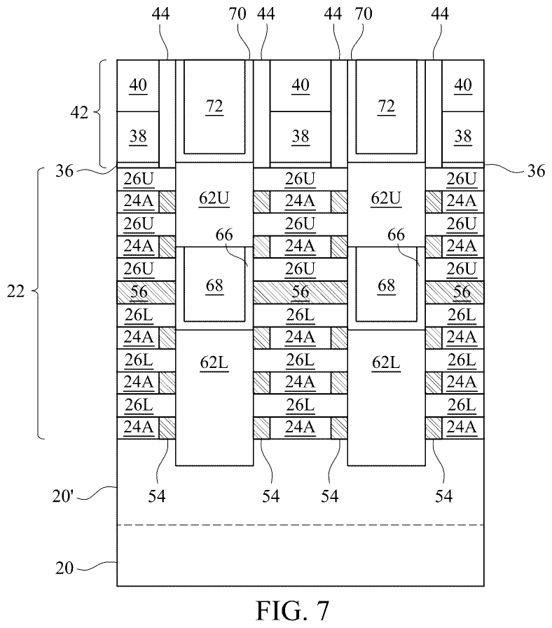

As also illustrated by FIG. 4, lower epitaxial source/drain regions 62L are formed. The lower epitaxial source/drain regions 62L are formed in the lower portions of the source/drain recesses 46. The lower epitaxial source/drain regions 62L are in contact with the lower semiconductor nanostructures 26L and are not in contact with upper semiconductor nanostructures 26U (not illustrated in FIG. 4 but illustrated and discussed further below with respect to FIG. 7). Inner spacers 54 electrically insulate the lower epitaxial source/drain regions 62L from the dummy nanostructures 24A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy of the lower epitaxial source/drain regions 62L, exposed surfaces of the upper semiconductor nanostructures 26U (e.g., sidewalls) may be masked to prevent undesired epitaxial growth on the upper semiconductor nanostructures 26U. After the lower epitaxial source/drain regions 62L are grown, the masks on the upper semiconductor nanostructures 26U may then be removed.

As a result of the epitaxy processes used for forming the lower epitaxial source/drain regions 62L, upper surfaces of the lower epitaxial source/drain regions 62L have facets which expand laterally outward beyond sidewalls of the multi-layer stacks 22. In some embodiments, adjacent lower epitaxial source/drain regions 62L remain separated after the epitaxy process is completed. In other embodiments, these facets cause neighboring lower epitaxial source/drain regions 62L of a same FET to merge.

A first contact etch stop layer (CESL) 66 and a first ILD 68 are formed over the lower epitaxial source/drain regions 62L. The first CESL 66 may be formed of a dielectric material having a high etching selectivity from the etching of the first ILD 68, such as silicon oxide, silicon nitride, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include silicon oxide, SiOC, SiON, phospho-silicate glass (PSG), boro-silicate glass (BSG), boron-doped phospho-silicate glass (BPSG), undoped silicate glass (USG), or the like. The formation processes may include depositing a conformal CESL layer, depositing a material for the first ILD 68, followed by a planarization process.

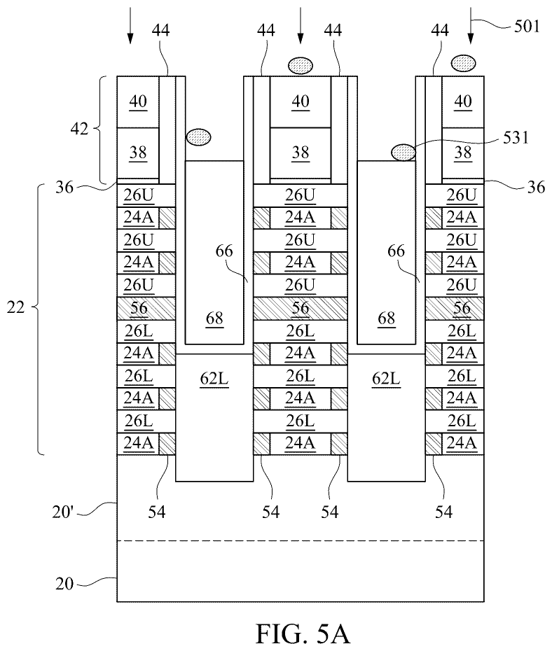

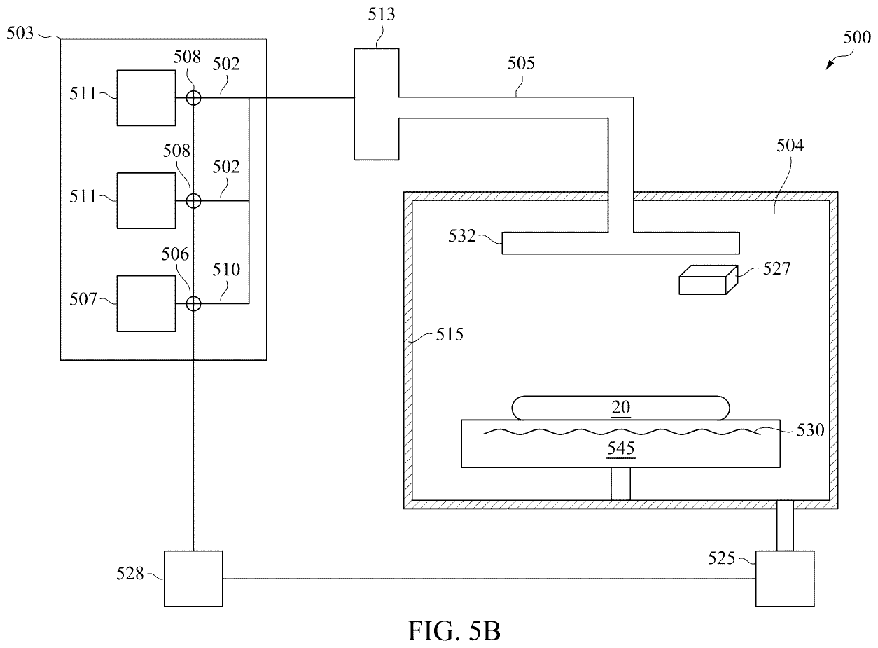

FIG. 5A illustrates a first part of a recessing of the first ILD 68. In an embodiment the first ILD 68 may be recessed using one or more etching processes (represented in FIG. 5A by the arrows labeled 501) using an etchant or combination of etchants that are selective to the material of the first ILD 68. As such, while the precise etchants that are used will be dependent at least in part on the material of the first ILD 68, in particular embodiments in which the first ILD 68 comprises silicon oxide, etchants such as hydrogen fluoride (HF) and ammonia (NH₃) may be utilized in order to recess the material of the first ILD 68. However, any suitable etchants may be utilized.

The etching process 501 may be initiated by placing the semiconductor substrate 20 into an etching system 500 such as the one illustrated in FIG. 5B. In some embodiments, the etching system 500 may comprise an etchant delivery system 503 that may deliver one or more gaseous etchants to an etching chamber 504. The etchant delivery system 503 supplies the various desired etchants to the etching chamber 504 through an etchant controller 513 and a manifold 505. The etchant delivery system 503 may also help to control the flow rate of the etchant or etchants into the etching chamber 504 by controlling the flow and pressure of a carrier gas through the etchant delivery system 503.

In an embodiment the etchant delivery system 503 may include a plurality of etchant suppliers 511 along with a carrier gas supply 507. While only two etchant suppliers 511 are illustrated in FIG. 5B, this is done merely for clarity, as any suitable number of etchant suppliers 511 may be utilized, such as one etchant supplier 511 for each etchant desired to be used within the etching system 500. For example, in an embodiment in which five separate etchants will be utilized, there may be five of the etchant suppliers 511.

Each of the etchant suppliers 511 may be a vessel, such as a gas storage tank, that is located either locally to the etching chamber 504 or remotely from the etching chamber 504. In other embodiments, the etchant supplier 511 may be a facility that independently prepares and delivers the desired etchants. Any suitable source for the desired etchants may be utilized as the etchant supplier 511, and all such sources are fully intended to be included within the scope of the embodiments.

In some embodiments, each of the etchant suppliers 511 supply an etchant to the etchant controller 513 through first lines 502 with first valves 508. The first valves 508 are controlled by a controller 528 that controls and regulates the introduction of the various etchants and carrier gases to the etching chamber 504.

A carrier gas supply 507 may supply a desired carrier gas, or diluent gas, that may be used to help push or “carry” the various desired etchants to the etching chamber 504. The carrier gas may be an inert gas or other gas that does not react with the etchant itself or with by-products from the etchant's reactions. For example, the carrier gas may be nitrogen (N₂), helium (He), argon (Ar), combinations of these, or the like, although other suitable carrier gases may be utilized.

The carrier gas supply 507, or diluent supply, may be a vessel, such as a gas storage tank, that is located either locally to the etching chamber 504 or remotely from the etching chamber 504. In other embodiments, the carrier gas supply 507 may be a facility that independently prepares and delivers the carrier gas to the etchant controller 513. Any suitable source for the carrier gas may be utilized as the carrier gas supply 507, and all such sources are fully intended to be included within the scope of the embodiments. The carrier gas supply 507 may supply the desired carrier gas to the etchant controller 513 through a second line 510 with a second valve 506 that connects the carrier gas supply 507 to the first lines 502. The second valve 506 is also controlled by the controller 528 that controls and regulates the introduction of the various etchants and carrier gases to the etching chamber 504. Once combined, the lines may be directed towards the etchant controller 513 for a controlled entry into the etching chamber 504.

The etching chamber 504 may be any desired shape that may be suitable for dispersing the etchant and contacting the etchant with the semiconductor substrate 20. In the embodiment illustrated in FIG. 5B, the etching chamber 504 has a cylindrical sidewall and a bottom. However, the etching chamber 504 is not limited to a cylindrical shape, and any other suitable shape, such as a hollow square tube, an octagonal shape, or the like, may be utilized. Furthermore, the etching chamber 504 may be surrounded by an etchant chamber housing 515 made of material that is inert to the various process materials. As such, while the etchant chamber housing 515 may be any suitable material that can withstand the chemistries and pressures involved in the etching process, in some embodiments the etchant chamber housing 515 may be steel, stainless steel, nickel, aluminum, alloys of these, combinations of these, and the like.

Additionally, the etching chamber 504 and the mounting platform 545 may be part of a cluster tool system (not shown). The cluster tool system may be used in conjunction with an automated handling system in order to position and place the semiconductor substrate 20 into the etching chamber 504 prior to the etching process, position and hold the semiconductor substrate 20 during the etching processes, and remove the semiconductor substrate 20 from the etching chamber 504 after the etching processes.

Within the etching chamber 504 is located a mounting platform 545 in order to position and control the semiconductor substrate 20 during the etching process. The mounting platform 345 may hold the semiconductor wafer 100 using electrostatic forces, clamps, vacuum pressure, combinations of these, or the like, and may also include heating and cooling mechanisms in order to control the temperature of the semiconductor substrate 20 during the processes.

Additionally, the mounting platform 545 may comprise one or more first heating elements 530 that are utilized to raise and control the temperature of the semiconductor substrate 20 during the etching process. In an embodiment the one or more first heating elements 530 may be a resistive heater or other type of heater in order to help control and maintain the temperature. However, any suitable type of heating element may be utilized.

In some embodiments the etching chamber 504 comprises a showerhead 532. In an embodiment the showerhead 532 receives the various etchants from the manifold 505 and helps to disperse the various etchants into the etching chamber 504. The showerhead 532 may be designed to evenly disperse the etchants in order to minimize undesired process conditions that may arise from uneven dispersal. In an embodiment the showerhead 532 may have a circular design with openings dispersed evenly around the showerhead 532 to allow for the dispersal of the desired etchants into the etching chamber 504. However, any suitable method of introducing the desired etchants, such as entry ports, may be utilized to introduce the desired etchants into the etching chamber 504.

The etching chamber 504 may also be connected to a vacuum pump 525. In an embodiment the vacuum pump 525 is under the control of the controller 528, and may be utilized to control the pressure within the etching chamber 504 to a desired pressure. Additionally, once the etching process is completed, the vacuum pump 525 may be utilized to evacuate the etching chamber 504 in preparation for removal of the semiconductor substrate 20.

Additionally while a number of particular parts of the etching system 500 have been described above, other suitable parts may also be included. For example, endpoint mounts, liners, and any other parts that may help operate or control the etching process may also be included. All such parts are fully intended to be included within the scope of the embodiments.

To begin to recess the first ILD 68, the process may be started by placing the semiconductor substrate 20 onto the mounting platform 545. Once the semiconductor substrate 20 has been placed onto the mounting platform 545, the semiconductor substrate 20 may be attached to the mounting platform 545 using an attachment process. In an embodiment in which the mounting platform 545 is an electrostatic chuck, the semiconductor substrate 20 may be attached to the mounting platform 545 by applying a first current (e.g., alternating current) such that electrostatic forces will apply a force to hold the semiconductor substrate 20 to the attachment surface of the mounting platform 545.

Once the semiconductor substrate 20 has been placed and is attached to the mounting platform 545, the controller 528 may initiate the recessing process by setting the temperature of the semiconductor substrate 20 using the first heating element 530. In an embodiment the first heating element 530 may be used to adjust the temperature to be between about −60° C. and about 80° C. However, any suitable temperature may be utilized.

Once the temperature has been set using the first heating element 530, the controller 528 may connect one or more of the etchant suppliers 511 and one of the carrier gas supply 507 to the etching chamber 504 to introduce a first etching combination of etchants (e.g., hydrogen fluoride (HF) and ammonia (NH₃)) to the semiconductor substrate 20. In the embodiment in which hydrogen fluoride and ammonia are utilized to recess the first ILD 68 when the first ILD 68 comprises silicon oxide, the etching process may react according to the following chemical equation:

$${SiO}_{2 ( g )} + 4 {HF}_{( g )} + 4 {NH}_{3 ( g )} \to {SiF}_{4 ( g )} + 2 {H}_{2} {O}_{( g )} + 4 {NH}_{3}$$

As can be seen, the silicon oxide will react with the etchants in order to form silicon fluoride (SiF₄) and water, thereby removing the material of the first ILD 68 from the structure.

However, the above described reaction is not the only reaction that occurs during the removal process, and other side reactions can occur in which undesired by-products 531 and/or salts can be created and remain within the source/drain recesses 46 and on the surface of the semiconductor substrate 20. As one example of such a side reaction, the silicon fluoride created in the main reaction may continue to react according to the following chemical equation:

$${SiF}_{4 ( g )} + 2 {HF}_{( g )} + 2 {NH}_{3 ( g )} \to {( {NH}_{4} )}_{2} {SiF}_{6 ( g )}$$

Such a side reaction will create an undesired by-product 531 such as ammonium hexafluorosilicate (AFS). Furthermore, this by-product 531 will be created as a solid within the source/drain recesses 46 being created. Unless this situation is ameliorated, the solid form of ammonium hexafluorosilicate will interfere with further etching, and may lead to a significant variations in the depths formed in different source/drain recesses 46.

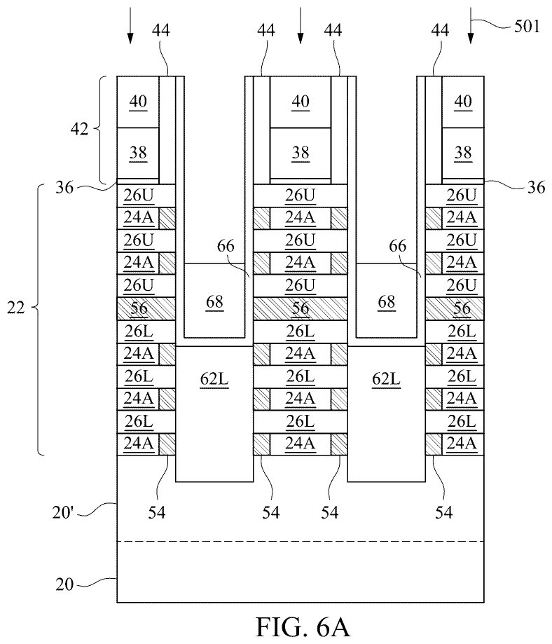

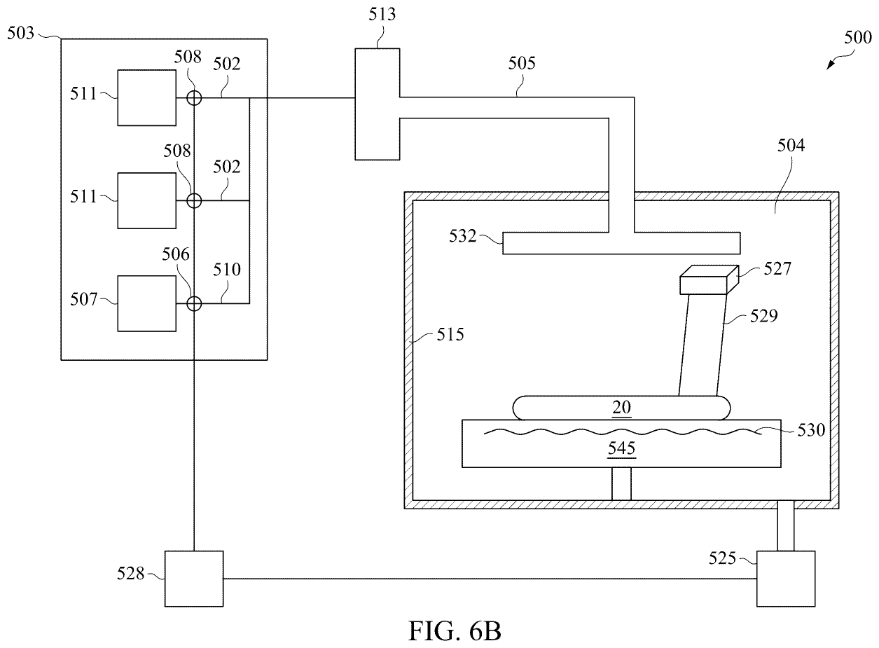

As such, as illustrated in FIG. 6A-6B, in order to assist in the removal of the undesired by-products 531 (e.g., ASF) so that the by-products 531 do not interfere with the remainder of the removal process 501, a secondary heating element 527 is included within the etching chamber 504. In one particular embodiment the secondary heating element 527 comprises a laser apparatus which can output a laser beam 529 towards the semiconductor substrate 20 and, more precisely, can output a laser beam 529 towards the undesired by-products 531 located within the source/drain recesses 46. In some embodiments the secondary heating element 527 can have a tunable direction in order to tune the angle of incidence of the laser beam 529 impinging on the semiconductor substrate 20.

In an embodiment the laser beam 529 is also tunable such that the laser beam 529 comprises one or more wavelengths of light that assists in the decomposition of the undesired by-product 531. For example, in an embodiment in which the undesired by-product 531 is AFS, the laser beam 529 comprises light along a spectrum, wherein the light along the spectrum is absorbed by the bonds present within the AFS (e.g., an AFS adsorption spectrum). By using such a spectrum, when the laser beam 529 impacts the AFS, decomposition of the AFS is facilitated by causing a decomposition according to the following chemical formula:

$${( {NH}_{4} )}_{2} {SiF}_{6 ( g )} \to {SiF}_{4 ( g )} + 2 {HF}_{( g )} + 2 {NH}_{3 ( g )}$$

By using the laser beam 529, the undesired by-products 531 may be more easily removed during the recessing of the first ILD 68. As such, without the by-products 531 present, the by-products 531 are not able to interfere with a remainder of the etching processes 501, and variation between different source/drain recesses 46 may be reduced.

FIG. 7 illustrates that, once the first ILD 68 has been recessed, an anisotropic etching process is then performed to remove the portions of the first CESL 66 higher than the recessed first ILD 68. After the recessing, the sidewalls of the upper semiconductor nanostructures 26U are exposed.

Upper epitaxial source/drain regions 62U are then formed in the upper portions of the source/drain recesses 46. The upper epitaxial source/drain regions 62U may be epitaxially grown from exposed surfaces of the upper semiconductor nanostructures 26U. The materials of upper epitaxial source/drain regions 62U may be selected from the same candidate group of materials for forming lower source/drain regions 62L, depending on the desired conductivity type of upper epitaxial source/drain regions 62U. The conductivity type of the upper epitaxial source/drain regions 62U may be opposite the conductivity type of the lower epitaxial source/drain regions 62L in embodiments where the stacking transistors are CFETs. For example, the upper epitaxial source/drain regions 62U may be oppositely doped from the lower epitaxial source/drain regions 62L. Alternatively, the conductivity types of the upper epitaxial source/drain regions 62U and the lower epitaxial source/drain regions 62L may be the same. The upper epitaxial source/drain regions 62U may be in-situ doped, and/or may be implanted, with an n-type or p-type dopant. Adjacent upper source/drain regions 62U may remain separated after the epitaxy process or may be merged.

After the epitaxial source/drain regions 62U are formed, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the masks 86 (if present) or the dummy gates 84 are substantially coplanar (within process variations). Accordingly, the top surfaces of the masks 40 (if present) or the dummy gates 38 are exposed through the second ILD 124. In the illustrated embodiment, the masks 40 remain after the removal process. In other embodiments, the masks 40 are removed such that the top surfaces of the dummy gates 38 are exposed through the second ILD 72.

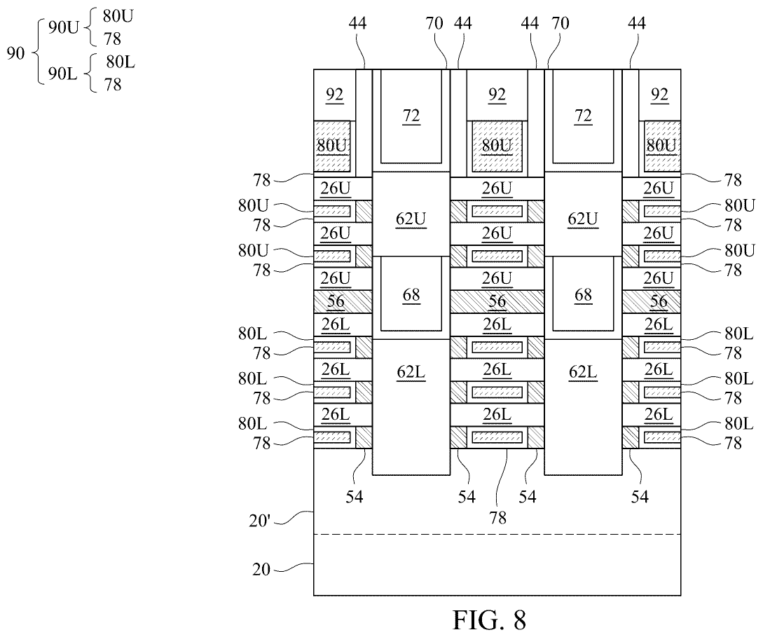

FIG. 8 illustrates a replacement gate process to replace the dummy gate stacks 42 and the dummy nanostructures 24A with gate stacks 90. The replacement gate process includes first removing the dummy gate stacks 42 and the remaining portions of the dummy nanostructures 24A. The dummy gate stacks 42 are removed in one or more etching processes, so that recesses are defined between the gate spacers 44 and the upper portions of the semiconductor strips 28 are exposed. The remaining portions of the dummy nanostructures 24A are then removed through etching, so that the recesses extend between the semiconductor nanostructures 26. In the etching process, the dummy nanostructures 24A is etched at a faster rate than the semiconductor nanostructures 26, the dielectric isolation layers 56, and the inner spacers 54. The etching may be isotropic. For example, when the dummy nanostructures 24A are formed of silicon-germanium, and the semiconductor nanostructures 26 are formed of silicon, the etch process may include a wet etch process using tetramethylammonium hydroxide (TMAH), ammonium hydroxide (NH₄OH), or the like.

Then, gate dielectrics 78 are deposited in the recesses between the gate spacers 44 and on the exposed semiconductor nanostructures 26. The gate dielectrics 78 are conformally formed on the exposed surfaces of the recesses (the removed gate stacks 42 and the dummy nanostructures 24A) including the semiconductor nanostructures 26 and the gate spacers 44. In some embodiments, the gate dielectrics 78 wrap around all (e.g., four) sides of the semiconductor nanostructures 26. Specifically, the gate dielectrics 78 may be formed on the top surfaces of the fins 20′; on the top surfaces, the sidewalls, and the bottom surfaces of the semiconductor nanostructures 26; and on the sidewalls of the gate spacers 90. The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 78 may include molecular-beam deposition (MBD), ALD, PECVD, and the like followed by a planarization process (e.g., a CMP) to remove portions of the gate dielectrics 78 above the second ILD 72. Although single-layered gate dielectrics 78 are illustrated, the gate dielectrics 78 may include multiple layers, such as an interfacial layer and an overlying high-k dielectric layer.

Lower gate electrodes 80L are formed on the gate dielectrics 78 around the lower semiconductor nanostructures 26L. For example, the lower gate electrodes 80L wrap around the lower semiconductor nanostructures 26L. The lower gate electrodes 80L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 80L may include any number of work function tuning layers, any number of barrier layers, any number of glue layers, and a fill material.

The lower gate electrodes 80L are formed of material(s) that are suitable for the device type of the lower nanostructure-FETs. For example, the lower gate electrodes 80L may include one or more work function tuning layer(s) formed of material(s) that are suitable for the device type of the lower nanostructure-FETs. In some embodiments, the lower gate electrodes 80L include an n-type work function tuning layer, which may be formed of titanium aluminum, titanium aluminum carbide, tantalum aluminum, tantalum carbide, combinations thereof, or the like. In some embodiments, the lower gate electrodes 80L include a p-type work function tuning layer, which may be formed of titanium nitride, tantalum nitride, combinations thereof, or the like. Additionally or alternatively, the lower gate electrodes 80L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The lower gate electrodes 80L may be formed by conformally depositing one or more gate electrode layer(s) recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 80L may expose the upper semiconductor nanostructures 26U.

In some embodiments, isolation layers (not explicitly illustrated) may be optionally formed on the lower gate electrodes 80L. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U.

Then, upper gate electrodes 80U are formed on the isolation layers described above (if present) or the lower gate electrodes 80L. The upper gate electrodes 80U are disposed between the upper semiconductor nanostructures 26U. In some embodiments, the upper gate electrodes 80U wrap around the upper semiconductor nanostructures 26U. The upper gate electrodes 80U may be formed of the same candidate materials and candidate processes for forming the lower gate electrodes 80L. The upper gate electrodes 80U are formed of material(s) that are suitable for the device type of the upper nanostructure-FETs. For example, the upper gate electrodes 80U may include one or more work function tuning layer(s) (e.g., n-type work function tuning layer(s) and/or p-type work function tuning layer(s)) formed of material(s) that are suitable for the device type of the upper nanostructure-FETs. Although single-layered gate electrodes 80U are illustrated, the upper gate electrodes 80U may include any number of work function tuning layers, any number of barrier layers, any number of glue layers, and a fill material.

Additionally, a removal process is performed to level top surfaces of the upper gate electrodes 80U and the second ILD 72. The removal process for forming the gate dielectrics 78 may be the same removal process as the removal process for forming the upper gate electrodes 80U. In some embodiments, a planarization process such as a chemical mechanical polish (CMP), an etch-back process, combinations thereof, or the like may be utilized. After the planarization process, the top surfaces of the upper gate electrodes 80U, the gate dielectrics 78, the second ILD 72, and the gate spacers 44 are substantially coplanar (within process variations). Each respective pair of a gate dielectric 78 and a gate electrode 80 (including an upper gate electrode 80U and/or a lower gate electrode 80L) may be collectively referred to as a “gate structure” 90 (including upper gate structures 90U and lower gate structures 90L). Each gate structure 90 extends along three sides (e.g., a top surface, a sidewall, and a bottom surface) of a channel region of a semiconductor nanostructure 26 (see FIG. 1). The lower gate structures 90L may also extend along sidewalls and/or a top surface of a semiconductor fin 20′.

As also shown in FIG. 8, gate masks 92 are formed over the gate stacks 42. The formation process may include recessing gate stacks 90, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 72.

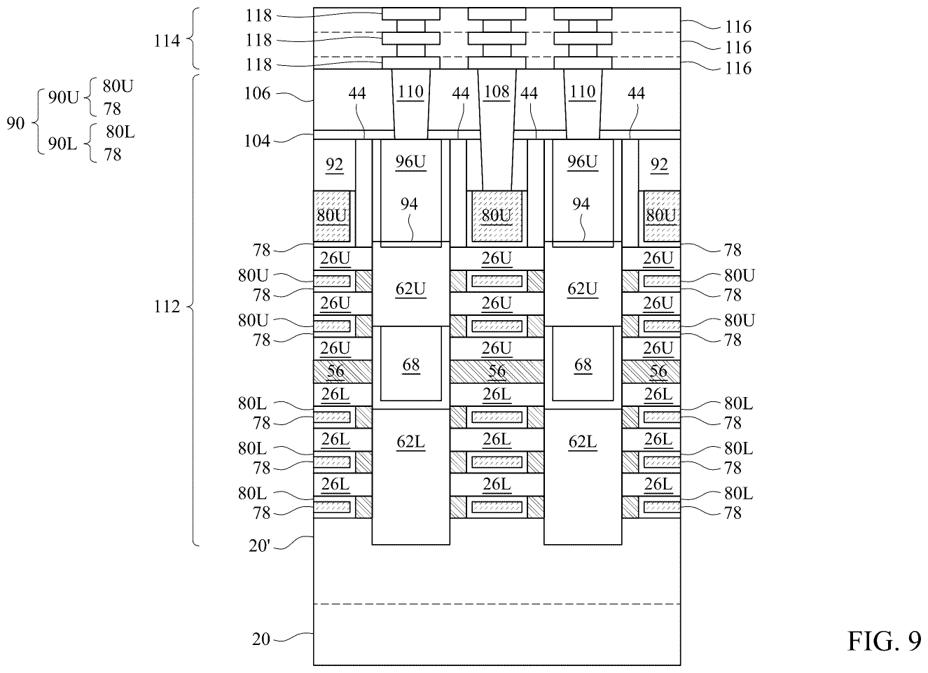

In FIG. 9, metal-semiconductor alloy regions 94 and source/drain contacts 96 are formed through the second ILD 72 to electrically couple to the upper epitaxial source/drain regions 62U and/or the lower epitaxial source/drain regions 62L. As an example to form the source/drain contacts 96, openings are formed through the second ILD 72 and the second CESL 70 using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 44 and the second ILD 72. The remaining liner and conductive material form the source/drain contacts 96 in the openings. In some embodiments, a planarization process such as a CMP, an etch-back process, combinations thereof, or the like is utilized. After the planarization process, the top surfaces of the gate spacers 44, the second ILD 72, and the source/drain contacts 96 are substantially coplanar (within process variations).

Optionally, metal-semiconductor alloy regions 94 are formed at the interfaces between the source/drain regions 62 and the source/drain contacts 96. The metal-semiconductor alloy regions 94 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 94 can be formed before the material(s) of the source/drain contacts 96 by depositing a metal in the openings for the source/drain contacts 96 and then performing a thermal anneal process. The metal can be any metal capable of reacting with the semiconductor materials (e.g., silicon, silicon-germanium, germanium, etc.) of the source/drain regions 62 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 96, such as from surfaces of the metal-semiconductor alloy regions 94. The material(s) of the source/drain contacts 96 can then be formed on the metal-semiconductor alloy regions 94.

An ESL 104 and a third ILD 106 are then formed. In some embodiments, The ESL 104 may include a dielectric material having a high etching selectivity from the etching of the third ILD 106, such as, aluminum oxide, aluminum nitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like.

Subsequently, gate contacts 108 and source/drain vias 110 are formed to contact the upper gate electrodes 80U and the source/drain contacts 96, respectively. As an example to form the gate contacts 108 and the source/drain vias 110, openings for the gate contacts 108 and the source/drain vias 110 are formed through the third ILD 106 and the ESL 104. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 106. The remaining liner and conductive material form the gate contacts 108 and the source/drain vias 110 in the openings. The gate contacts 108 and the source/drain vias 110 may be formed in distinct processes, or may be formed in the same process. Although shown as being formed in the same cross-section, it should be appreciated that each of the gate contacts 108 and the source/drain vias 110 may be formed in different cross-sections, which may avoid shorting of the contacts.

A front-side interconnect structure 114 is formed on the device layer 112. The front-side interconnect structure 114 includes dielectric layers 116 and layers of conductive features 118 in the dielectric layers 116. The dielectric layers 116 may include low-k dielectric layers formed of low-k dielectric materials. The dielectric layers 116 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 116 may also include polymer layers.

The conductive features 118 may include conductive lines and vias, which may be formed using damascene processes. Conductive features 118 may include metal lines and metal vias, which includes diffusion barriers and a copper containing material over the diffusion barriers. There may also be aluminum pads over and electrically connected to the metal lines and vias. In some embodiments, contacts to the lower gate structure 90L and the lower source/drain regions 80L may be made through a backside of the device layer 112 (e.g., a side opposite to the front-side interconnect structure 114).

By utilizing the secondary heating element 527, an independent heating of the undesired by-products 531 may be achieved. Additionally, this heating is separate and independent from the heating that is controlled by the first heating element 530. As such, with such independent heating, the by-products 531 may be removed and decomposed without affecting the remainder of the etching process.

Additionally, while the above description describes the use of the secondary heating element 527 as occurring after the initiation of the etching processes 501, this is not intended to limit the embodiments. Rather, the secondary heating element 527 may be initiated at any desired point in the process, such as simultaneously with the initiation of the etching processes 501.

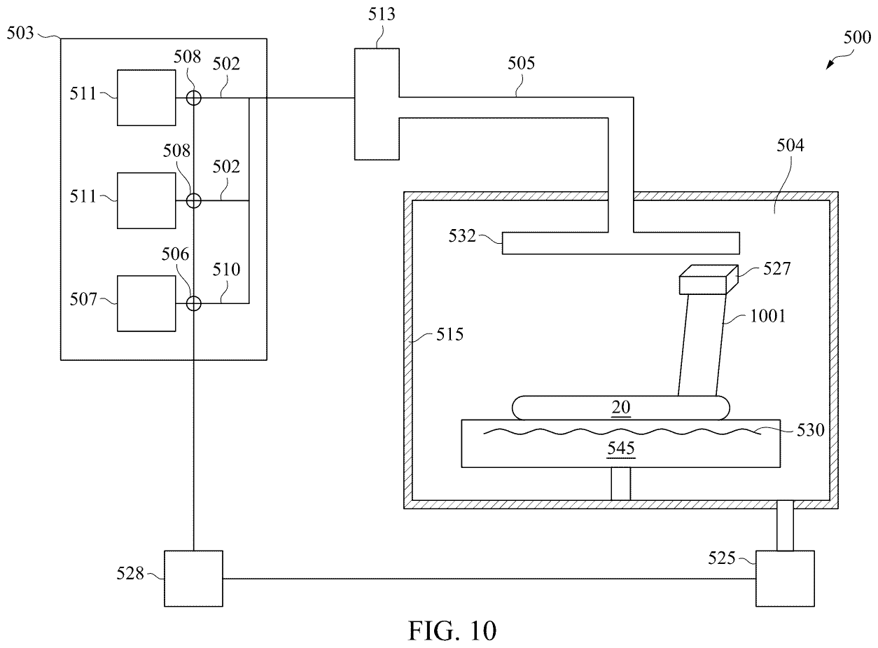

FIG. 10 illustrates another embodiment of the secondary heating element 527. In this embodiment, instead of the secondary heating element 527 being a laser that outputs a laser beam (as described above with respect to FIG. 5B), the secondary heating element 527 may be a ultraviolet light emitter, an infrared light emitter, a light emitting diode (LED), or vacuum ultra-violet emitter that outputs a light beam 1001. However, any suitable wavelengths of light may be utilized.

Additionally, in some embodiments the secondary heating element 527 may be tunable with respect to both the wavelength of light that being output and also tunable with respect to the scanning. For example, in some embodiments the wavelength of light that is being generated may be tuned based in part on at least the by-product 531 that is desired to be decomposed. Additionally, if the output light beam 1001 is not large enough to illuminate all of the desired area, a scanning process may be utilized, wherein one or more of the semiconductor substrate 20 or the secondary heating element 527 are rotated with respect to each other. Any suitable tuning may be utilized.

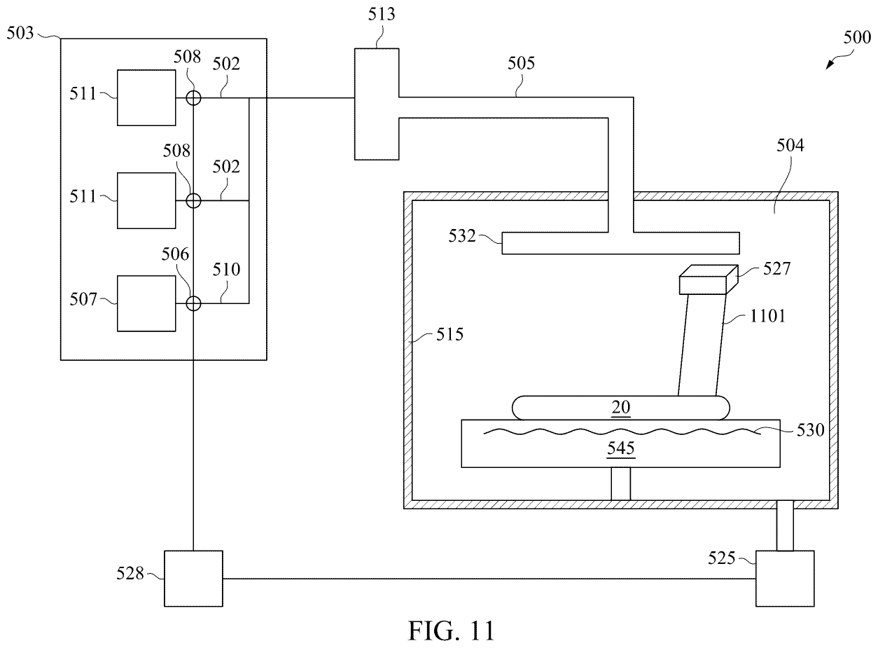

FIG. 11 illustrates another embodiment of the secondary heating element 527. In this embodiment, instead of the secondary heating element 527 being a laser that outputs a laser beam (as described above with respect to FIG. 5B) or a light emitting diode LED (as described above with respect to FIG. 10), the secondary heating element 527 may be an electron beam generator. In this embodiment the secondary heating element 527 outputs an electron beam 1101 that works to independently heat the by-products 531 separately from the remainder of the semiconductor substrate 20.

Additionally in this embodiment the secondary heating element 527 may be tunable with respect to both the wavelength and incident angle of the electron beam 1101 that is being output and also tunable with respect to the scanning. For example, in some embodiments the wavelength of the electron beam 1101 that is being generated may be tuned based in part on at least the by-product 531 that is desired. Additionally, if the output electron beam 1101 is not large enough to illuminate all of the desired area, a scanning process may be utilized, wherein one or more of the semiconductor substrate 20 or the secondary heating element 527 are rotated with respect to each other.

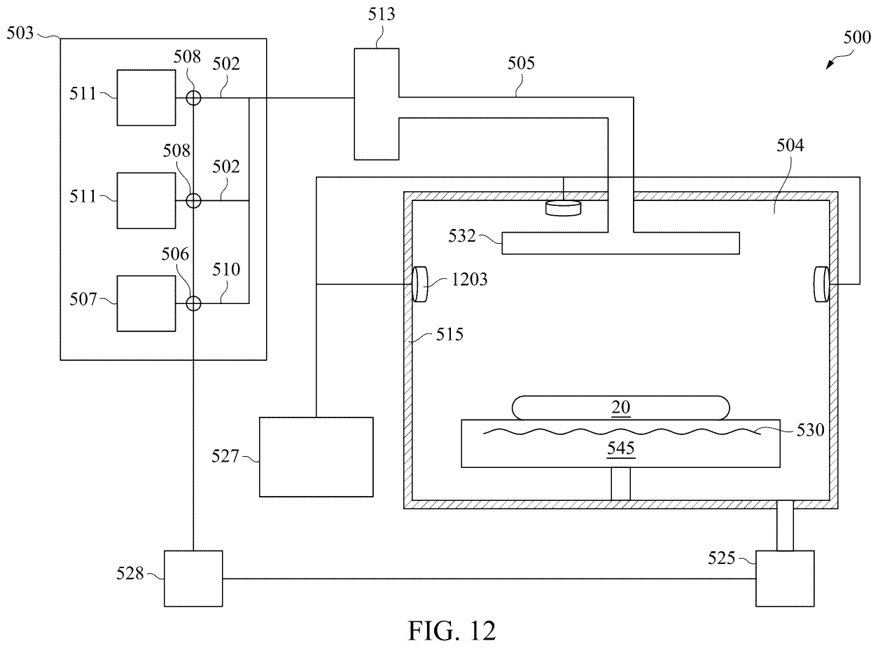

FIG. 12 illustrates another embodiment of the secondary heating element 527. In this embodiment, instead of the secondary heating element 527 being a laser that outputs a laser beam (as described above with respect to FIG. 5B), a light emitting diode LED (as described above with respect to FIG. 10), or an electron beam generator (as described above with respect to FIG. 11), the secondary heating element 527 may be a hot neutral injection device. In this embodiment the secondary heating element 527 inputs gases or radicals into the etching chamber 504 from, e.g., a neutral heating box 1201. In an embodiment the neutral heating box 1201 receives gases and/or radicals and heats the gases and/or radicals using a heating method such as a laser, microwave (MW), light emitting diodes, plasma processes, combinations of these, or the like. However, any suitable methods of heating may be utilized.

Once the gases and/or radicals have been heated within the neutral heating box 1201, the gases and/or radicals are injected into the etching chamber 504 through one or more secondary showerheads 1203. In an embodiment the one or more secondary showerheads 1203 may be similar to the showerhead 532 (described above with respect to FIG. 5B). However, any suitable method or devices may be used to inject the heaters neutrals into the etching chamber 504.

Additionally in this embodiment the secondary heating element 527 may be tunable with respect to the introduction of the hot neutrals. For example, if the introduction of the hot neutrals is not large enough to introduce the hot neutrals to all of the desired area, a scanning process may be utilized, wherein one or more of the semiconductor substrate 20 or the secondary heating element 527 are rotated with respect to each other.

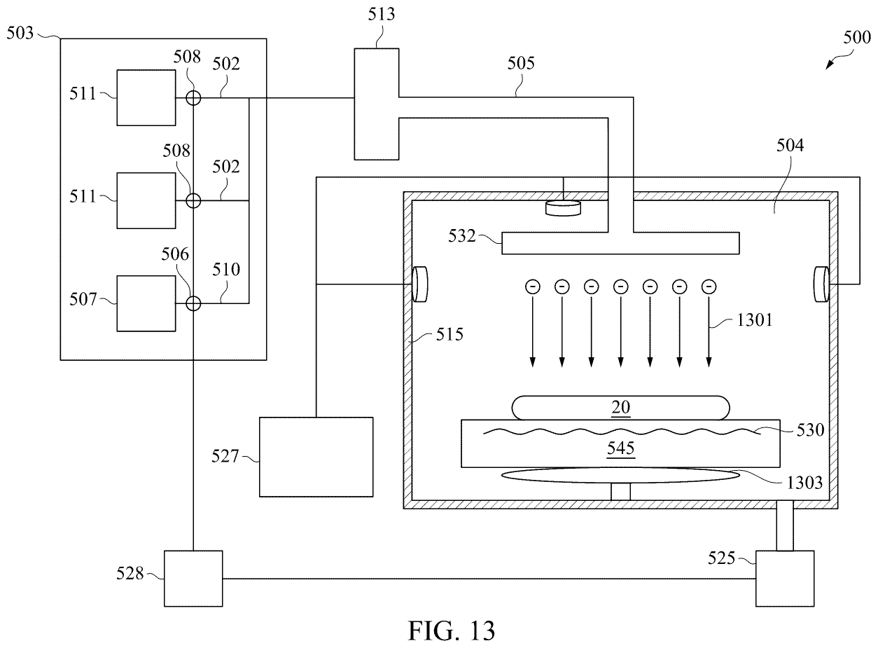

FIG. 13 illustrates yet another embodiment of the secondary heating element 527. In this embodiment, instead of the secondary heating element 527 being a laser that outputs a laser beam (as described above with respect to FIG. 5B), a light emitting diode LED (as described above with respect to FIG. 10), an electron beam generator (as described above with respect to FIG. 11), or a hot neutral injector (as described above with respect to FIG. 12), the secondary heating element 527 may be an electron bombardment device. In this embodiment the secondary heating element 527 inputs electrons 1301 into the etching chamber 504 from, e.g., an electron injector. Once the electrons 1301 have been injected into the etching chamber 504, an electrode 1303 can be utilized in order to provide a DC bias to accelerate the electrons 1301 towards the semiconductor substrate 20.

Of course, while a particular number of embodiments has been presented above, the ideas are not intended to be limited to the precise embodiments described. Rather, any other suitable method of independently heating the by-products 531 such that the by-products 531 decompose may be utilized. All such methods are fully intended to be included within the scope of the embodiments.

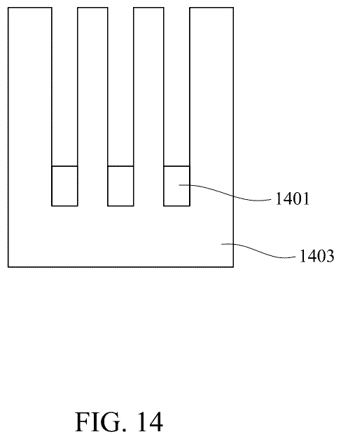

FIG. 14 illustrates that, while a particular structure has been presented above, the ideas presented are not intended to be limited to the precise structures as described. Rather, the ideas may be utilized on any suitable material (e.g., a first material 1401) that is being recessed within any other suitable material (e.g., a second material 1403). In such embodiments the first material 1401 may be a material such as silicon oxide, silicon oxycarbide, silicon oxynitride, combinations of these, or the like, while the second material 1403 may be a material such as silicon, silicon nitride, silicon carbonitride, SiOCN, aluminum oxide, titanium nitride, tungsten, combinations of these, or the like. However, any suitable materials may be utilized.

Once the first material 1401 has been deposited within the second material 1403, the first material 1401 is recessed. The first material 1401 may be recessed using the processes described above with respect to FIGS. 1-14, including using an independent heating source in order to heat and decompose undesired by-products 531 during the etching processes 501. As such, the by-products 531 may be removed and do not interfere with the remaining parts of the etch processes 501.

By utilizing the embodiment described herein, an independent heating source is utilized in order to remove the by-products 531 and salts that are generated during the chemical etch process. This function enables the temperatures control of the semiconductor substrate 20 and the by-products 531 to be separated from each other. Such separation helps to improve the depth variation and avoid a drop in the etch rate by using a general high temperature.

In accordance with an embodiment, a method of manufacturing a semiconductor device includes: depositing a dielectric material into a trench over a semiconductor substrate; recessing the dielectric material with an etching process, wherein the etching process includes: heating the semiconductor substrate; and separately heating a by-product of the etching process. In an embodiment the by-product is ammonium hexafluorosilicate. In an embodiment the separately heating is performed at least in part with a laser. In an embodiment the separately heating is performed at least in part with a light emitting diode. In an embodiment the separately heating is performed at least in part with electron injection. In an embodiment the separately heating is performed at least in part with hot neutrals. In an embodiment the separately heating is performed at least in part with an electron beam.

In accordance with another embodiment, a method of manufacturing a semiconductor device includes: placing a semiconductor wafer into an etching chamber, the etching chamber comprising a first heating element, the semiconductor wafer comprising a dielectric material located within a first recess; reacting the dielectric material to form a gas and recess the dielectric material, the reacting the dielectric material additionally creating a by-product; and heating the by-product with a second heating element different from the first heating element. In an embodiment the second heating element is an electron injector. In an embodiment the second heating element is an electron beam generator. In an embodiment the second heating element is a neutral heating box. In an embodiment the second heating element is a light emitting diode. In an embodiment the second heating element is a laser. In an embodiment the by-product is ammonium hexafluorosilicate.

In accordance with yet another embodiment, an apparatus for manufacturing a semiconductor device, the apparatus including: an etching chamber; a mounting platform; a first heating element; and a second heating element independent from the first heating element. In an embodiment the first heating element is a resistive heating element. In an embodiment the second heating element is a laser. In an embodiment the second heating element is an electron beam. In an embodiment the second heating element is a light emitting diode. In an embodiment the second heating element is an infrared generator.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, the method comprising:
depositing a dielectric material into a trench over a semiconductor substrate; and
recessing the dielectric material with an etching process, wherein the etching process comprises:
heating the semiconductor substrate; and
separately heating a by-product of the etching process.

2. The method of claim 1, wherein the by-product is ammonium hexafluorosilicate.

3. The method of claim 1, wherein the separately heating is performed at least in part with a laser.

4. The method of claim 1, wherein the separately heating is performed at least in part with a light emitting diode.

5. The method of claim 1, wherein the separately heating is performed at least in part with electron injection.

6. The method of claim 1, wherein the separately heating is performed at least in part with hot neutrals.

7. The method of claim 1, wherein the separately heating is performed at least in part with an electron beam.

8. A method of manufacturing a semiconductor device, the method comprising:
placing a semiconductor wafer into an etching chamber, the etching chamber comprising a first heating element, the semiconductor wafer comprising a dielectric material located within a first recess;
reacting the dielectric material to form a gas and recess the dielectric material, the reacting the dielectric material additionally creating a by-product; and
heating the by-product with a second heating element different from the first heating element.

9. The method of claim 8, wherein the second heating element is an electron injector.

10. The method of claim 8, wherein the second heating element is an electron beam generator.

11. The method of claim 8, wherein the second heating element is a neutral heating box.

12. The method of claim 8, wherein the second heating element is a light emitting diode.

13. The method of claim 8, wherein the second heating element is a laser.

14. The method of claim 8, wherein the by-product is ammonium hexafluorosilicate.

15. An apparatus for manufacturing a semiconductor device, the apparatus comprising:
an etching chamber:
a mounting platform;
a first heating element; and
a second heating element independent from the first heating element.

16. The apparatus of claim 15, wherein the first heating element is a resistive heating element.

17. The apparatus of claim 16, wherein the second heating element is a laser.

18. The apparatus of claim 16, wherein the second heating element is an electron beam.

19. The apparatus of claim 16, wherein the second heating element is a light emitting diode.

20. The apparatus of claim 16, wherein the second heating element is an infrared generator.
